(19) United States
(12) Patent Application Publication
(10) Pub. No.: US 2004/0018667 A1
(43) Pub. Date: Jan. 29, 2004

(54) Method and apparatus for producing a silicon wafer chip package

(76) Inventors: Haren Joshi, Cupertino, CA (US); Ralph Alan Griffin, Fremont, CA (US)

Correspondence Address: CENTRAL COAST PATENT AGENCY, PO BOX 187, AROMAS, CA, 95004, US

(21) Appl. No.: 10/206,281

(22) Filed: Jul. 26, 2002

(51) Int. Cl. H01L 21/44; H01L 21/48; H01L 21/50

(52) U.S. Cl. 438/126; 438/460

(57) ABSTRACT

A method for packaging discrete and integrated circuit (IC) die each having a pattern of input/output (I/O) pads has steps of (a) forming a first pattern of openings through a thickness of a silicon substrate wafer in a plurality of die attach positions, and metallizing through the openings; (b) attaching the IC die to a first surface of the wafer in individual ones of the plurality of positions; (c) electrically connecting individual ICs from the I/O pads to the metallized vias; (d) covering the attached and I/O-connected ICs on the first surface with an encapsulation material, forming a laminate encapsulating the ICs on the wafer; and (e) singulating the laminate into individual packages comprising at least one encapsulated IC on a silicon substrate having a pattern of electrical contacts on an outside surface of the substrate communicating electrically with I/O pads on the encapsulated IC. The substrate wafer can be a reclaimed wafer.

### FIELD OF THE INVENTION

The present invention is in the field of semiconductor chip packaging, and pertains more particularly to a method and apparatus for using viable or reclaimed wafers as a component in packaging.

### BACKGROUND OF THE INVENTION

In the field of semiconductor manufacturing and processing the art of chip packaging continually undergoes evolution and change, resulting in new packaging materials, package construction and encapsulation methods and apparatus. The most common method of chip mounting and packaging in the current art involves metal lead frame technology and polymer encapsulation techniques. More recently, chip-scale packaging has been introduced. All of these prior art techniques require multi-step processes that are complex and subject to failure under less than strict control.

Past efforts to miniaturize chip packaging have been concentrated in the areas of no-lead packaging. In this effort, both ceramic and organic substrates have been used to produce surface mount land grid array (LGA), ball grid array (BGA), and quad-flat no-lead (QFN) packages. These types of packages are less than economical to produce and are subject to thermal expansion mismatch between the die material and the surrounding packaging materials.

A technique known to the inventor is used to construct a chip scale package wherein process steps inherent to normal chip construction are reduced somewhat by providing a wafer blank laminated to an active circuit surface of a die, the wafer blank having apertures opening to the die providing conductive access to the die for chip mounting purposes. The method is described in a published U.S. patent application Ser. No. 09/769,983 entitled “Micro-Machined Chip Scale Package” filed on Jan. 25, 2001 and in process of examination at the current time of this application. While the processes taught in this prior application can be conducted at wafer level, the resulting singulated products are die-size products that still have to be tested, mounted, and encapsulated if the die itself is to be fully protected. Processes such as lead-frame production and encapsulation are still required.

It is desired that much of the tedious process involved in semiconductor packaging be streamlined as much as possible in a highly reliable manner. Therefore what is clearly needed is an improved method for chip packaging that can be conducted at wafer level and that also provides complete protection for the mounted die.

### SUMMARY OF THE INVENTION

In a preferred embodiment of the present invention a method for packaging integrated circuit (IC) die each having a pattern of input/output (I/O) pads is provided, comprising the steps of (a) forming a first pattern of openings through a thickness of a silicon substrate wafer in a plurality of die attach positions, and metalizing through the openings; (b) attaching the IC die to a first surface of the wafer in individual ones of the plurality of positions; (c) electrically connecting individual ICs from the I/O pads to the metallized vias; (d) covering the attached and I/O-connected ICs on the first surface with an encapsulation material, forming a laminate encapsulating the ICs on the wafer; and (e) singulating the laminate into individual packages comprising at least one encapsulated IC on a silicon substrate having a pattern of electrical contacts on an outside surface of the substrate communicating electrically with I/O pads on the encapsulated IC.

In a preferred embodiment the wafer is a reclaimed wafer having circuitry on an active surface, and further comprising a step for removing the circuitry and thinning the wafer. Also in some embodiments the encapsulation material is a polymer material, which may be applied by spinning or molding. In preferred embodiments as well, there may be a step or steps for forming electrical bonding pads or conductive traces on one or both sides of the substrate wafer. In some embodiments dielectric material is used at individual ones of the die attach positions, forming die attach pads for mounting individual ones of the IC die.

In various embodiments electrical connection is made between a die and through holes by one of wire bonding or flip-chip techniques. There may also be a step before singulation for electrically testing individual ones of the encapsulated die. Still further, there may be solder bumps or land patterns electrically connected to the metallized vias on the side of the wafer opposite the encapsulated IC die, to facilitate subsequent mounting of singulated packages to printed circuit boards or other circuitry.

In some embodiments meant for demanding environments, the encapsulation material may be a second silicon wafer having cavities in one surface in the pattern of the plurality of die attach positions, and further comprising a step for joining the two wafers surface to surface such that individual ones of the attached die are enclosed in individual ones of the cavities. The wafers may be joined by a glass fritseal or by other suitable techniques.

In some other embodiments the encapsulation material is formed from a spacer wafer having through-openings of a size to enclose individual die attached to positions on the substrate wafer, and a cap wafer, wherein the spacer wafer is joined to the substrate wafer surrounding individual ones of the attached die, and the cap wafer is joined to the spacer wafer as a lid, completing enclosure of the individual die. Again the joining may be by a glass fritseal or by other suitable techniques.

In another aspect of the invention an integrated circuit (IC) package is provided, comprising a silicon substrate having a pattern of metal-filled through-openings between a first and a second side, an IC die attached to the silicon substrate on a first side, electrical connections from input-output (I/O) pads on the die to the metal-filled through openings, and an encapsulation structure encapsulating the die and electrical connections on the first side of the substrate.

In some preferred embodiments substrate is from a reclaimed wafer having circuitry on an active surface, and the circuitry is removed, thinning the wafer, before the die is mounted. The encapsulation structure may be a polymer material completely covering the die and the connections, which may be applied by one of spinning or molding.

In some cases there are further electrical bonding pads or conductive traces on one or both sides of the substrate, and in some cases there are dielectric die attach pads at individual ones of the die attach positions, forming die attach pads for mounting individual ones of the IC die. The electrical connections may be wires from die I/O points to through-vias, or more direct solder connections by flip-chip technique. There may further be solder bumps electrically connected to the metal-filled through-openings on a second side of the substrate, for subsequent connection to a printed circuit board or other circuitry.

In some embodiments the encapsulation structure comprises a silicon enclosure element having a cavity in one surface of an extent and volume to enclose the mounted die and connections, wherein the silicon substrate and the enclosure element are joined to completely encapsulate the die and connections. These are joined in some embodiments by a glass fritseal or by other suitable techniques. The encapsulation structure may also comprise a spacer wafer having a through-opening of a size to enclose the die and connections, and a cap wafer, the spacer wafer joined to the substrate wafer and the cap wafer joined to the spacer wafer as a lid, completing enclosure of the die. Again, these elements may be joined by glass frit or other suitable techniques.

In various embodiments of the invention taught in enabling detail below, for the first time a packaging method and package is provided in the art that allows encapsulated packages to be formed using singulated die without a need for lead frames or the attendant processes; and in some embodiments packages are provided with complete silicon enclosure for especially challenging environments.

### BRIEF DESCRIPTION OF THE DRAWING FIGURES

FIG. 1 is a plan view of a silicon wafer used as a base substrate for silicon packaging according to an embodiment of the present invention.

FIG. 2 is a rear view of the wafer of FIG. 1 illustrating via openings placed therein according to an embodiment of the present invention.

FIG. 3 is a partial section and elevation plan view of a substrate wafer with die mounted and wire bonded according to one embodiment of the present invention.

FIG. 4 is a plan view of a cap wafer having cavities for enclosing die in an embodiment of the invention.

FIG. 5 is an elevation view of a wafer package containing a substrate, spacer and cover of silicon wafer material according to another embodiment of the present invention.

### DESCRIPTION OF PREFERRED EMBODIMENTS

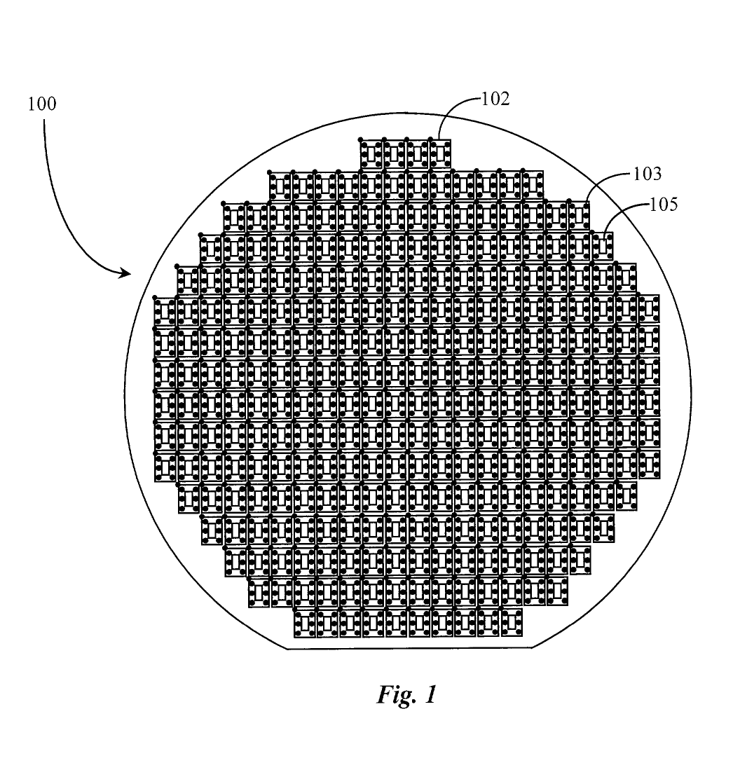

FIG. 1 is a plan view of a silicon wafer 100 used as a base substrate for silicon packaging according to an embodiment of the present invention. Silicon wafer 100 can be a raw wafer procured from a wafer producer or in some preferred embodiments wafer 100 can be a recycled wafer supporting circuitry that is obsolete or reclaimed. As part of preparation of substrate wafer 100 for die attach it is thinned from the standard wafer thickness of about 700 microns to an approximate range between 75 microns to 450 microns. This process, in the case of recycled wafers, serves to remove all of the circuitry and other material on the wafer. Wafer 100 is a standard 150 mm diameter wafer in this example however the process can be used in conjunction with differing diameter wafers.

After wafer 100 has been thinned to the appropriate thickness and all unwanted materials, if any, are thereby removed, a plurality of strategically located and dimensionally controlled via openings 103 are created through the remaining thickness of the wafer. Openings 103 may be drilled by laser, ionically etched into the wafer, or etched through wet etch methods that are known to and available to the inventor and to the skilled artisan. In the case of the RIE or wet etch methods a suitable hard mask may be created through standard deposition growth and lithographic techniques.

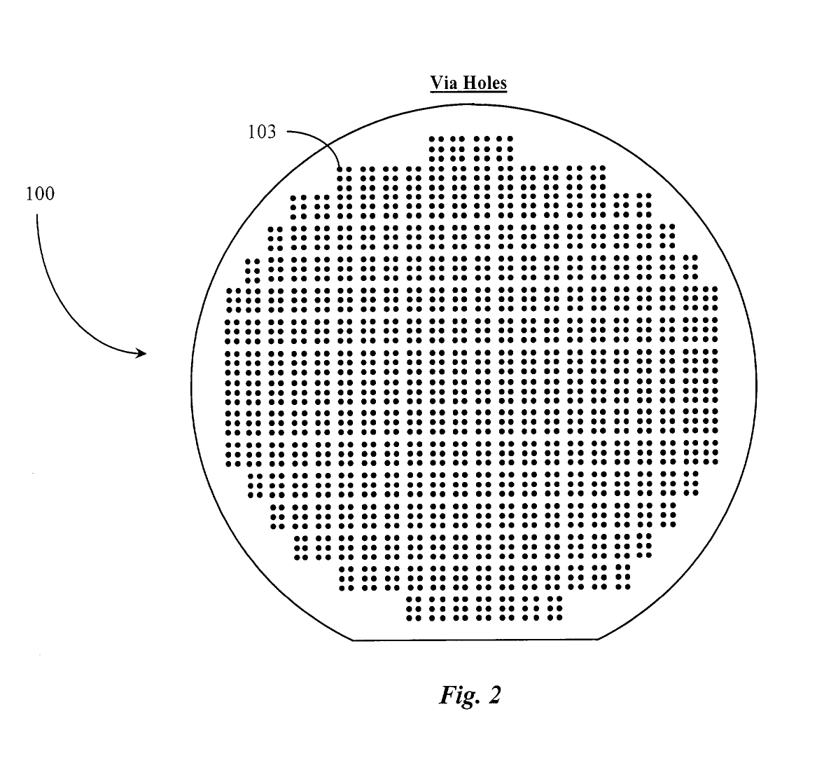

FIG. 2 is a plan view of the backside of wafer 100 of FIG. 1 illustrating via openings 103 placed therethrough according to an embodiment of the present invention. After openings 103 are formed through wafer 100, the wafer is coated with a conductive metal on both sides in a manner creating continuous metal traces through the openings 103, forming conductive paths through the substrate wafer. Other techniques, such as electroless plating may also be used to fill the vias through the substrate wafer. Next metal conductive traces 102 (if needed) and die attach pads 105 are formed by conventional techniques on one or both sides of the substrate wafer from the metal film deposited. The dielectric die attach pads may be screened using a mask. The prepared substrate wafer may be thought of as a new sort of lead frame. Traces 102 can be formed through vacuum deposition techniques or by sputtering metals using contact masks. Similarly a continuous metallic layer may be sputtered, deposited by vacuum, or plated followed by standard lithography and wet etch methods to remove the undesired metal, leaving the wanted traces and land pads.

Assuming a prepared substrate wafer according to the above descriptions, device chips are first singulated from a wafer and then mounted to the dielectric die attach pads on the substrate wafer. In some embodiments the die are mounted with edge I/O pads facing upward (away from the substrate wafer), then wire bonding technology is used to connect the I/O pads on individual die to bond pads and traces on the substrate wafer, leading to through vias 103. In other embodiments Flip Chip techniques may be used, providing solder balls on either the substrate wafer or the die, and then mounting the die face down to the traces on the substrate wafer.

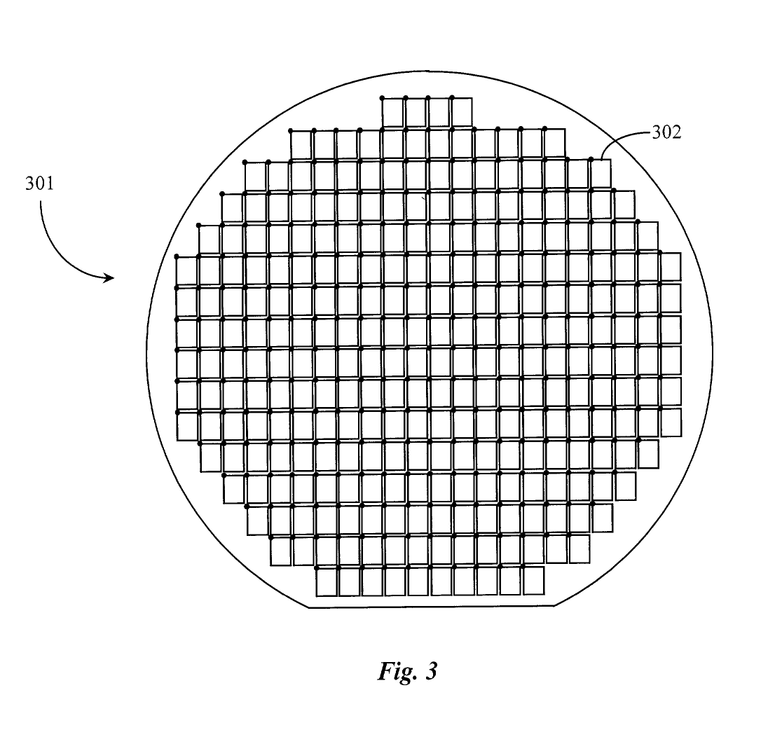

FIG. 3 is a partial section view in elevation of an assembly 300 including substrate wafer 100 with dies 302 attached and wire bonding (wires 301) accomplished and connecting through metal-filled vias 103 as described above. There may be one via per wire bond, but this is not a functional limitation. In this example, assembly 300 has been provided with solder bumps or balls on the underside as a means of connection for subsequently separated, packaged die to a printed circuit board or other circuitry component.

In a next step in this example the assembly is covered with encapsulation material 307, which may be applied in any number of ways, such as by spinning, potting, molding and the like. This material is provided in a single operation encapsulating all of the die attached and bonded on substrate 100.

Either before or after encapsulation wafer level testing may be done. Rejects may be suitably marked or otherwise recorded. In this embodiment, the entire process is performed at wafer level. The encapsulated and tested assembly is then singulated along scribe lines 304 to separate the good packages into individual encapsulated die for shipment to customers. In one embodiment, a package sliced from the finished substrate may contain more than one die. Note that lead-frame molding processes have been avoided and wafer level manufacturing has been achieved.

It will be apparent to one with skill in the art that the method of the present invention in the exemplary embodiment described above provides low cost silicon packages and enables avoidance of time consuming lead-frame processes otherwise required and providing distinct size advantage over standard lead frame packages.

High Reliability Packaging

According to one embodiment of the present invention a thermally resistant, highly reliable semiconductor package is provided wherein no encapsulation material is required in order to protect the die.

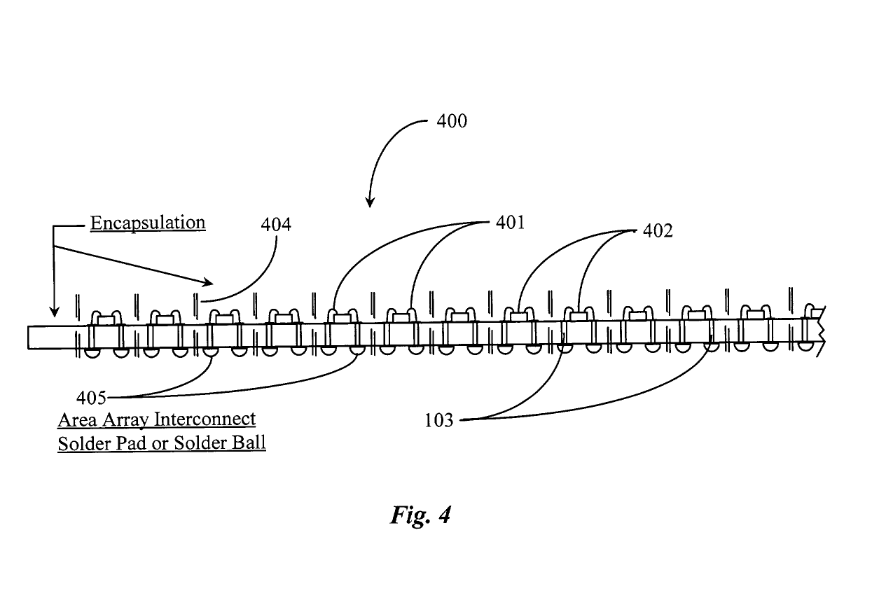

FIG. 4 is a plan view of a silicon cap wafer 400 used in packaging according to one embodiment of the present invention. Wafer 400 is used in place of encapsulation procedures described above, wherein encapsulation material is applied to assembly 300. Wafer 400 can be a new wafer or a recycled wafer as was described with reference to FIG. 1 above. Wafer 400 is also thinned down in a preferred embodiment by machining process from about 27 mils to a thickness somewhat greater than the height of the attached die and bonded wires on finished substrate wafer 100 as shown in FIG. 3, and cavities 402 are machined or etched into the wafer, but not through the wafer, providing volumes for enclosing die.

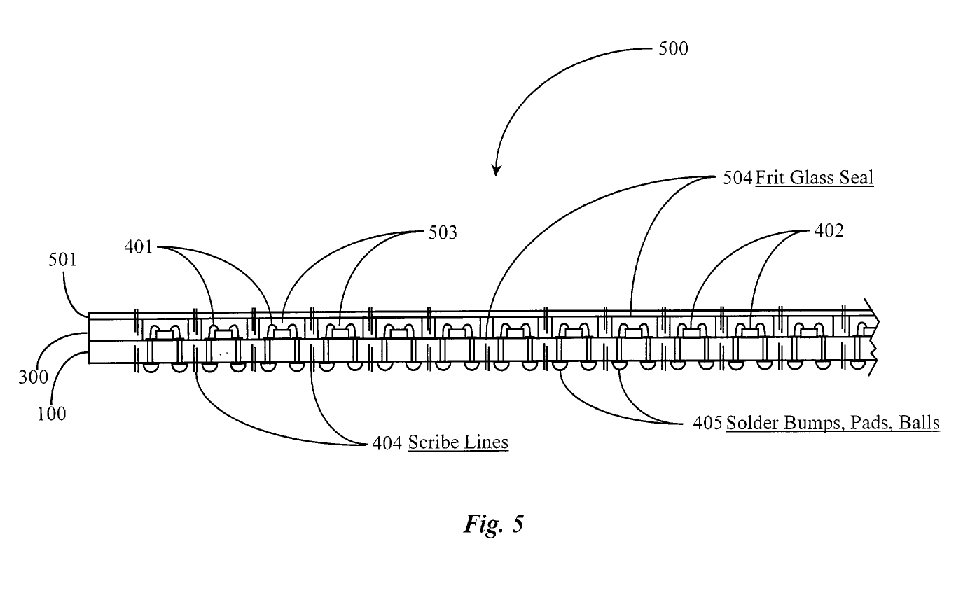

FIG. 5 is an elevation view in partial section of an assembly 500 in a preferred embodiment of the invention. The cap wafer 400 is inverted, placed over assembly 300 such that the cavities formed in the cap wafer surround each of the attached die, and the two wafers are sealed together in a preferred embodiment using glass frit 504. Other techniques may also be used to seal the two wafers together, and in the process each of the attached die are enclosed in volumes 503. After the two wafers are joined, singulation is done, again along separation lines 304. In this embodiment no encapsulation material is necessary.

In an alternative embodiment cavities 402 are formed completely through spacer wafer 400, and a lid wafer as implied by line 501 in FIG. 5, is sealed at the top to finally enclose the die in separate cavities. The lid, or cover wafer can also be a recycled wafer. In both the described methods, testing and reject identification followed by slicing takes place after sealing or encapsulation. Finished products identified as good packages are then ready for shipment to customers.

It will be apparent to the skilled artisan, given the unique descriptions and teaching herein, that the packages produced using all silicon enclosure will be more reliable in high temperature applications than conventional packages that use materials of greatly differing coefficients of thermal expansion. Moreover, the innovative packages can withstand longer exposure to thermal extremes in operation. This preferred embodiment may replace traditional ceramic packages used in high reliability applications. Wafer level production is achieved and both lead frame technologies and traditional polymer encapsulation techniques have been avoided, eliminating many process steps from traditional device packaging.

The method and apparatus of the invention provides a low cost and reliable wafer-level device packaging process for encapsulated packages while avoiding lead-frame technology. The method and apparatus of the invention in various embodiments also provides an economical wafer-level construction of thermally-resistant, high-reliability packages that resist typical thermal differences inherent to other prior-art devices.

The method and apparatus of the invention should be afforded the broadest scope under examination. The method and apparatus of the present invention is limited only by the claims that follow.

What is claimed is:

1. A method for packaging integrated circuit (IC) die each having a pattern of input/output (I/O) pads, comprising the steps of:
(a) forming a first pattern of openings through a thickness of a silicon substrate wafer in a plurality of die attach positions, and metallizing through the openings;
(b) attaching the IC die to a first surface of the wafer in individual ones of the plurality of positions;
(c) electrically connecting individual ICs from the I/O pads to the metallized vias;
(d) covering the attached and I/O-connected ICs on the first surface with an encapsulation material, forming a laminate encapsulating the ICs on the wafer; and
(e) singulating the laminate into individual packages comprising at least one encapsulated IC on a silicon substrate having a pattern of electrical contacts on an outside surface of the substrate communicating electrically with I/O pads on the encapsulated IC.

2. The method of claim 1 wherein the wafer is a reclaimed wafer having circuitry on an active surface, and further comprising a step for removing the circuitry and thinning the wafer.

3. The method of claim 1 wherein in step (d) the encapsulation material is a polymer material.

4. The method of claim 3 wherein the polymer material is applied by one of spinning or molding.

5. The method of claim 1 further comprising a step or steps for forming electrical bonding pads or conductive traces on one or both sides of the substrate wafer.

6. The method of claim 1 further comprising steps for applying dielectric material at individual ones of the die attach positions, forming die attach pads for mounting individual ones of the IC die.

7. The method of claim 1 wherein electrical connection is made by one of wire bonding or flip-chip techniques.

8. The method of claim 1 further comprising a step before singulation for electrically testing individual ones of the encapsulated die.

9. The method of claim 1 further comprising a step for forming solder bumps electrically connected to the metallized vias on the side of the wafer opposite the encapsulated IC die, to facilitate subsequent mounting of singulated packages to printed circuit boards or other circuitry.

10. The method of claim 1 wherein in step (d) the encapsulation material is a second silicon wafer having cavities in one surface in the pattern of the plurality of die attach positions, and further comprising a step for joining the two wafers surface to surface such that individual ones of the attached die are enclosed in individual ones of the cavities.

11. The method of claim 10 wherein the two wafers are joined by a glass fritseal.

12. The method of claim 1 wherein the encapsulation material is formed from a spacer wafer having through-openings of a size to enclose individual die attached to positions on the substrate wafer, and a cap wafer, wherein the spacer wafer is joined to the substrate wafer surrounding individual ones of the attached die, and the cap wafer is joined to the spacer wafer as a lid, completing enclosure of the individual die.

13. The method of claim 12 wherein the joining of wafer to wafer is by a glass fritseal.

14. An integrated circuit (IC) package, comprising:
(a) a silicon substrate having a pattern of metal-filled through-openings between a first and a second side;
(b) an IC die attached to the silicon substrate on a first side;
(c) electrical connections from input-output (I/O) pads on the die to the metal-filled through openings; and
(d) an encapsulation structure encapsulating the die and electrical connections on the first side of the substrate.

15. The package of claim 14 wherein the substrate is from a reclaimed wafer having circuitry on an active surface, and the circuitry is removed, thinning the wafer, before the die is mounted.

16. The package of claim 14 wherein encapsulation structure is a polymer material completely covering the die and the connections.

17. The package of claim 16 wherein the polymer material is applied by one of spinning or molding.

18. The package of claim 14 further comprising electrical bonding pads or conductive traces on one or both sides of the substrate.

19. The package of claim 14 further comprising a dielectric die attach pad upon which the die is mounted.

20. The package of claim 14 wherein the electrical connections are wires from the die I/O pads to the metal-filled through openings.

21. The package of claim 14 further comprising solder bumps electrically connected to the metal-filled through-openings on a second side of the substrate.

22. The package of claim 14 wherein the encapsulation structure comprises a silicon enclosure element having a cavity in one surface of an extent and volume to enclose the mounted die and connections, wherein the silicon substrate and the enclosure element are joined to completely encapsulate the die and connections.

23. The package of claim 22 wherein the silicon substrate and the silicon enclosure element are joined by a glass fritseal.

24. The package of claim 14 wherein the encapsulation structure comprises a spacer wafer having a through-opening of a size to enclose the die and connections, and a cap wafer, the spacer wafer joined to the substrate wafer and the cap wafer joined to the spacer wafer as a lid, completing enclosure of the die.

25. The package of claim 24 wherein the joining of silicon to silicon is by a glass fritseal.
